(19) United States
(12) Patent Application Publication
(10) Pub. No.: US 2004/0169501 A1
(43) Pub. Date: Sep. 2, 2004

(54) Magnitude and polarity measurement of static charge

(76) Inventor: Gerald L. Munson, Madison, CT (US)

Correspondence Address: JOHN H CROZIER, 1934 HUNTINGTON TURNPIKE, TRUMBULL, CT, 06611

(21) Appl. No.: 10/482,147

(22) PCT Filed: Jun. 21, 2002
(86) PCT No.: PCT/US02/19635

Related U.S. Application Data
(60) Provisional application No. 60/300,522, filed on Jun. 22, 2001.

(51) Int. Cl. G01R 33/12

(52) U.S. Cl. 324/204; 324/71.1; 324/220; 324/453; 73/861.13

(57) ABSTRACT

In a preferred embodiment, a sensor (10) for measuring magnitude and polarity of static charge on particles in a liquid, including: an electrically nonconductive conduit (26) through which the particles and the liquid can flow; a magnet (20) having first and second legs (22,24) with a gap therebetween, the gap being disposed in the conduit; and three electrodes (40, 42, 44) insulatedly disposed in the first leg and having distal ends protruding into the gap. A method of measuring magnitude and polarity of static charge on particles in a liquid is also provided.

### TECHNICAL FIELD

The present invention relates to magnitude and polarity measurement of static charge generally and, more particularly, to the measurement of the magnitude and polarity of static charge on particles in a liquid.

### BACKGROUND ART

Particles in a liquid that is in motion will tend to become electro statically charged. Electrostatic charges are transferred from the containment vessel to the particle in accordance with the types of materials constituting the particle and the containment vessel and the velocity of the encounter between the two objects. Having achieved this electrostatic charge, the particle will remain charged until encountering a conductive mass of sufficiently low resistivity to dissipate the charge. Charges of like polarity will tend to repel each other in accordance with Coulombs Law and, therefore, will be self-sustaining.

As the number and electrostatic charge level of individual particles increase, the electro potential of the liquid can become problematic. Electrochemical reactions can be unintentionally put in motion that is both unanticipated and undesirable. Therefore, the measurement of both the quantity of particles carrying electrical charge and the potential level of that charge on an average particle basis can be advantageous, as that information can be used to control particle removal equipment. Such a system is described, for example, in U.S. Pat. No. 5,788,827, issued Aug. 4, 1998, to Gerald L. Munson, and titled MEANS AND METHOD FOR REMOVING PARTICULATE MATTER FROM NONCONDUCTIVE LIQUIDS, the disclosure of which patent is incorporated by reference hereinto.

Accordingly, it is a principal object of the present invention to provide a means and a method for measuring the magnitude and polarity of electrostatic charge on particles in a liquid.

It is a further object of the invention to provide such means and method that can be economically constructed.

Other objects of the present invention, as well as particular features, elements, and advantages thereof, will be elucidated in, or be apparent from, the following description and the accompanying drawing figures

### DISCLOSURE OF INVENTION

The present invention achieves the above objects, among others, by providing, in a preferred embodiment, a sensor for measuring magnitude and polarity of static charge on particles in a liquid, comprising: (a) an electrically nonconductive conduit through which said particles and said liquid can flow; (b) a magnet having first and second legs with a gap therebetween, said gap being disposed in said conduit; and (c) three electrodes insulatedly disposed in said first leg and having distal ends protruding into said gap. A method of measuring magnitude and polarity of static charge on particles in a liquid is also provided.

### BRIEF DESCRIPTION OF DRAWINGS

Understanding of the present invention and the various aspects thereof will be facilitated by reference to the accompanying drawing figures, provided for purposes of illustration only and not intended to define the scope of the invention, on which:

FIG. 1 is an end elevational view, partially in cross-section, of the device of the present invention.

FIG. 2 is a side elevational view of the device.

### BEST MODE FOR CARRYING OUT THE INVENTION

Reference should now be made to the drawing figures on which similar or identical elements are given consistent identifying numerals throughout the various figures thereof, and on which parenthetical references to figure numbers, when used, direct the reader to the view(s) on which the element(s) being described is (are) best seen, although the element(s) may be seen on other figures also.

Charged particles passing through an electromagnetic field react with the field and create distortions in that field in accordance with their velocity and coulometric electrical charge. The device of the present invention permits the conversion of the transit of charged particles though a high flux density magnetic field to be sensed as electrical impulses on the electrodes of the device.

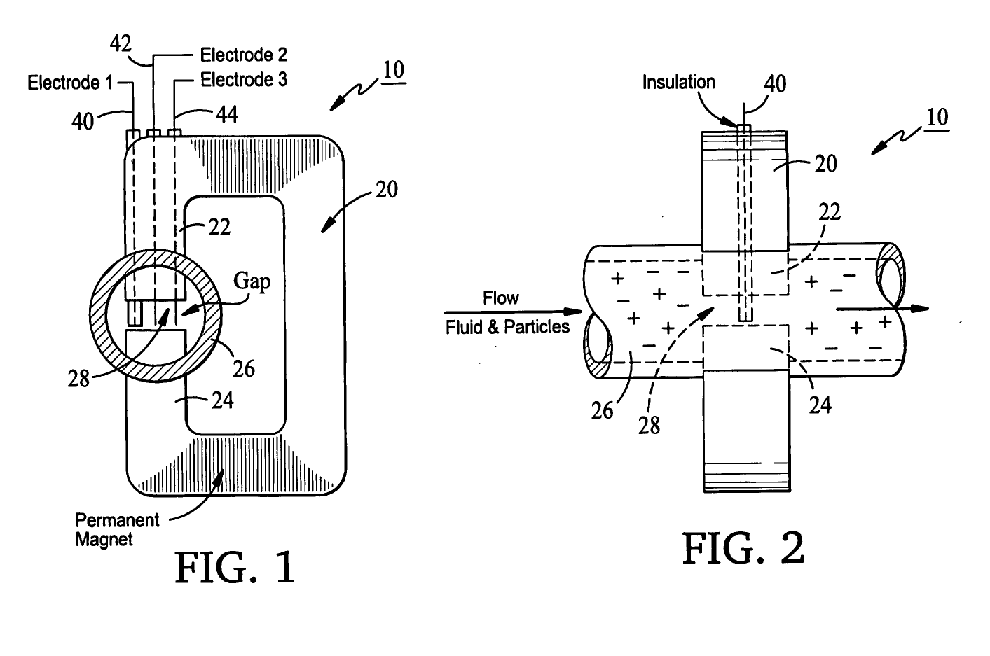

FIGS. 1 and 2 illustrate a device for measuring the magnitude and polarity of the charge on particles in a liquid, constructed according to the present invention, and generally indicated by the reference numeral 10. Device 10 includes a permanent magnet 20 having first and second legs 22 and 24, respectively, sealingly inserted in a electrically nonconductive liquid conduit such that a gap 28 formed therebetween is disposed in the conduit. Three electrodes, 40, 42, and 44 are insulatedly inserted in first leg 22 such that their distal ends protrude into gap 28. Permanent magnet 20 creates a magnetic field nearly parallel to electrodes 40, 42, and 44.

The distal end of electrode 40 is insulated such that all pulses created at the electrode will be as the result of charges particles passing near the electrode.

The distal end of electrode 42 (FIG. 1) is bare and exposed to the particles, permitting direct contact between the particulate and that electrode. Electrode 42 creates a signal which is the sum of the pulses created by the excursions of charged particulate near that electrode and the charge transferred to that electrode due to direct contact with the conductive charged particles.

The distal end of electrode 44 (FIG. 1) is also bare and that electrode is swept with a high impedance triangular waveform such that the summation of the various signals may be measured as a function of the potential applied to the electrode. This method can determine the range of potential which can effectively move electrostatic charge onto the passing particulate in an efficient manner. For reasonable flow rates and low potentials, electrode 44 will only interact with particles having potential opposite to the applied potential.

A hex modal signal will be produced for:

positive particle passing near electrode 40

negative particles passing near electrode 40

for particles which have a potential, or a diameter too small to come into contact with electrode 42, at very low impressed positive potential

for particles which have a potential, or a diameter too small to come into contact with electrode 42, at very low impressed negative potential

for particles which come into contact with electrode 44 and which have a substantial positive charge and will react in accordance with the unit charge of the electron potential applied in excess

for particles which come into contact with electrode 44 and which have a substantial negative charge and will react in accordance with the unit charge of the electron potential applied in excess.

So arranged, device 10 can measure the quantity of charged particles per unit volume of liquid, the quantity of particles of positive charge, the quantity of particles of negative charge, the level of charge on positively charged particles, and the level of charge on negatively charged particles.

The range of particle sizes and the liquids under consideration may be the same as described in the above-referenced patent and device 10 may be substituted for charge sensor 24 in purification system 20 shown in that patent.

In the embodiments of the present invention described above, it will be recognized that individual elements and/or features thereof are not necessarily limited to a particular embodiment but, where applicable, are interchangeable and can be used in any selected embodiment even though such may not be specifically shown.

Terms such as “above”, “below”, “uppee”, “lower”, “inner”, “outer”, “inwardly”, “outwardly”, “vertical”, “horizontal”, and the like, when used herein, refer to the positions of the respective elements shown on the accompanying drawing figures and the present invention is not necessarily limited to such positions.

It will thus be seen that the objects set forth above, among those elucidated in, or made apparent from, the preceding description, are efficiently attained and, since certain changes may be made in the above construction without departing from the scope of the invention, it is intended that all matter contained in the above description or shown on the accompanying drawing figures shall be interpreted as illustrative only and not in a limiting sense.

It is also to be understood that the following claims are intended to cover all of the generic and specific features of the invention herein described and all statements of the scope of the invention which, as a matter of language, might be said to fall therebetween.

1. A sensor for measuring magnitude and polarity of static charge on particles in a liquid, comprising:
(a) an electrically nonconductive conduit through which said particles and said liquid can flow;
(b) a magnet having first and second legs with a gap therebetween, said gap being disposed in said conduit; and
(c) three electrodes insulatedly disposed in said first leg and having distal ends protruding into said gap.

2. A sensor, as defined in claim 1, wherein: a distal end of one of said three electrodes is insulated and distal ends of two of said three electrodes are bare.

3. A sensor, as defined in claim 1, wherein: a major axis of said magnet is orthogonal to a major axis of said conduit.

4. A sensor, as defined in claim 1, wherein: said magnet is a permanent magnet.

5. A method of measuring magnitude and polarity of static charge on particles in a liquid, comprising:
(a) exposing to said particles distal ends of three electrodes protruding into a gap formed between first and second legs of a magnet; and
(b) sweeping one of said electrodes with a high impedance triangular waveform to produce a hex modal signal.

6. A method, as defined in claim 5, further comprising: providing said electrodes insulatedly disposed through said first leg of said magnet.

7. A method, as defined in claim 5, further comprising: providing said gap disposed in an electrically nonconductive conduit through which said particles and said liquid flow.

8. A method, as defined in claim 5, wherein: said hex modal signal is produced for positive particle passing near said one of said electrodes.

9. A method, as defined in claim 5, wherein: said hex modal signal is produced for negative particles passing near said one of said electrodes.

10. A method, as defined in claim 5, wherein: said hex modal signal is produced for particles which have a potential, or a diameter too small to come into contact with said one of said electrodes, at very low impressed positive potential.

11. A method, as defined in claim 5, wherein: said hex modal signal is produced for particles which have a potential, or a diameter too small to come into contact with said one of said electrodes, at very low impressed negative potential.

12. A method, as defined in claim 5, wherein: said hex modal signal is produced for particles which have a substantial positive charge and will react in accordance with the unit charge of the electron potential applied in excess.

13. A method, as defined in claim 5, wherein: said hex modal signal is produced for particles which have a substantial negative charge and will react in accordance with the unit charge of the electron potential applied in excess.
